(19) United States
(12) Patent Application Publication
(10) Pub. No.: US 2009/0215206 A1
(43) Pub. Date: Aug. 27, 2009

(54) System and method for controlling a semiconductor manufacturing process

(75) Inventors: Abeer Singhal, Richmond, VA (US); Christopher Gould, Quinton, VA (US); William Roberts, Mechanicsville, VA (US)

Correspondence Address: POSZ LAW GROUP, PLC, 12040 SOUTH LAKES DRIVE, SUITE 101, RESTON, VA, 20191, US

(73) Assignee: QIMONDA NORTH AMERICA CORP, Cary, NC (US)

(21) Appl. No.: 12/071,721

(22) Filed: Feb. 26, 2008

(51) Int. Cl. H01L 21/66

(52) U.S. Cl. 438/17; 438/14; 257/E21.531

(57) ABSTRACT

A semiconductor manufacture and testing device is provided, comprising: a process device configured to perform a semiconductor processing operation on a semiconductor wafer; a testing device configured to perform a testing operation on the semiconductor wafer and generate real-time testing metrics relating to the testing operation; a data storage element configured to store the real-time testing metrics as stored testing metrics; a control and dispatch element configured to receive the stored testing metrics and generate dispatch control signals based on the stored testing metrics and a set of evaluation rules; and a test routing element located between the process element and the testing element, and configured to route the semiconductor wafer either from the process element to the testing element or from the process element around the testing element, based the dispatch control signals.

### FIELD OF THE INVENTION

The present invention relates in general to a semiconductor fabrication system and process, and in particular to a device and method for controlling the processing and testing of semiconductor materials as they pass through a manufacturing process.

### BACKGROUND OF THE INVENTION

Semiconductor fabrication is a complicated process, and one that generally does not achieve a 100% yield, particularly as lot sizes increase. In other words, when a batch of semiconductor wafers (i.e., a lot) is processed in a fabrication facility, generally not all of the final wafers will be usable. Sometimes errors are caused by improper positioning of wafers or processing equipment. Because of the small size of elements being formed on the wafers, extreme precision required for proper manufacture of semiconductor devices on the wafers. In some parts of the process even an extremely small positional error can result in a defective wafer. Other times errors are caused by malfunctioning equipment that does not properly perform its required processing operations. In addition, other errors are, of course, possible.

Regardless of the cause, the various possible errors make testing an important part of the fabrication process. By testing, the manufacturer can get rid of wafers that aren't functional, and get rid of them as soon after the errors have been made so that expensive processing is not performed on already defective wafers. In addition, to the extent that errors can be identified and corrected early, the overall yield of the fabrication process can be increased by minimizing fabrication errors.

Conventional manufacturing facilities use sampling control systems along with stand-alone statistical process control (SPC) systems to control wafer or lot testing. Using these systems, a sampling rate for the wafers can be set. Based on this sampling rate, wafers or lots of wafers are randomly tested during the fabrication process. For example, if the likelihood of error is considered high, the sampling rate could be set such that every wafer lot is tested. But if the likelihood of error is considered lower, the sampling rate could be set such that every third lot, or every tenth lot, or every hundredth lot were tested, as appropriate.

Typically, this sampling rate is manually set by an operator. Over time, as conditions change, the operator can alter the sampling rate as needed. However, such changes are, by their nature, slow. Sometimes a higher sampling rate is warranted, but a lower sampling rate is used. This can result in a lower yield as defective wafers pass through without being properly tested. Likewise, sometimes a lower sampling rate is warranted, but a higher sampling rate is used. This can result in an unnecessarily slow fabrication process and the wasting of resources as perfectly good wafers are tested unnecessarily.

This becomes more pronounced in high part mix factories. A high part mix factory is a facility that encompasses products and parts of different technology nodes (e.g., 110 nm, 90 nm, 65 nm) and different product designs (e.g., memory, logic, RFID, etc.). Such a high part mix factory allows for many different kinds of products to be manufactured in the same factory, allowing much greater flexibility for a fabrication company. But the probability of errors goes up in a high part mix fabrication setting, because of the potential variation in processing operations and parameters. In particular, high part mix coupled with variable distributed volume manufacturing makes it difficult to meet factory production goals, cycle time goals, measurement/inspection capacity, capital costs, and floor space constraints.

It would therefore be desirable to provide an intelligent sampling mechanism and method that allows the amount and degree of testing to be dynamically varied as needed based on information gathered during the fabrication process.

### SUMMARY OF THE INVENTION

A semiconductor manufacture and testing device, comprising: a process device configured to perform a semiconductor processing operation on a semiconductor wafer; a testing device configured to perform a testing operation on the semiconductor wafer and generate real-time testing metrics relating to the testing operation; a data storage element configured to store the real-time testing metrics as stored testing metrics; a control and dispatch element configured to receive the stored testing metrics and generate dispatch control signals based on the stored testing metrics and a set of evaluation rules; and a test routing element located between the process element and the testing element, and configured to route the semiconductor wafer either from the process element to the testing element or from the process element around the testing element, based the dispatch control signals.

### BRIEF DESCRIPTION OF THE DRAWINGS

The accompanying figures where like reference numerals refer to identical or functionally similar elements and which together with the detailed description below are incorporated in and form part of the specification, serve to further illustrate an exemplary embodiment and to explain various principles and advantages in accordance with the present invention.

FIG. 1 is a block diagram of a semiconductor manufacturing facility according to disclosed embodiments;

FIG. 2 is a block diagram of a portion of the semiconductor manufacturing facility of FIG. 1 according to disclosed embodiments;

FIG. 3 is a block diagram of a portion of the testing equipment of FIGS. 1 and 2 according to disclosed embodiments;

FIG. 4 is a block diagram of a portion of the set of databases of FIG. 2 according to disclosed embodiments;

FIG. 5 is a block diagram of a portion of the controller of FIG. 2 according to disclosed embodiments;

FIG. 6 is a flow chart of the operation of the routing mechanism of FIGS. 1 and 2 according to disclosed embodiments; and

FIG. 7 is a flow chart of the operation of the testing equipment of FIGS. 1-3 according to disclosed embodiments.

### DETAILED DESCRIPTION

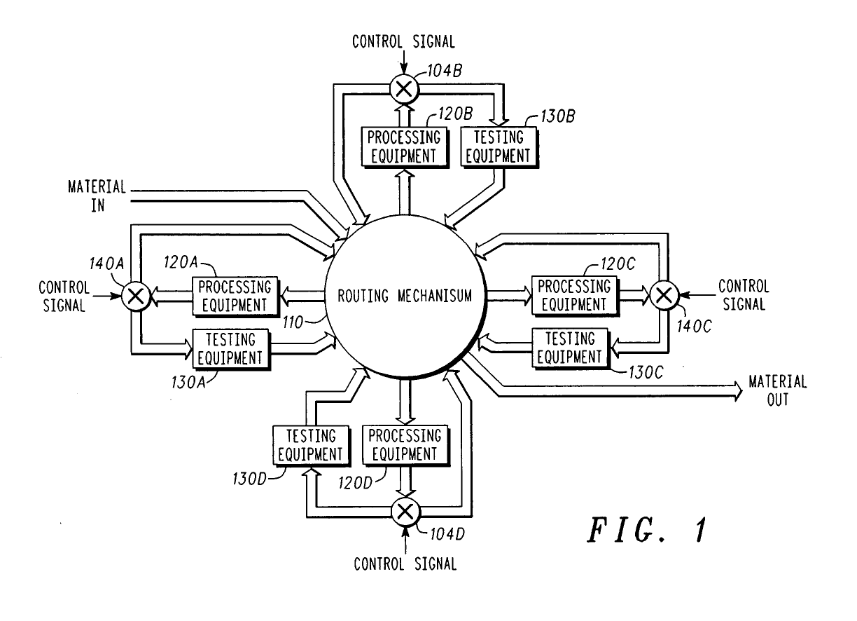

FIG. 1 is a block diagram of a semiconductor manufacturing facility 100 according to disclosed embodiments. As shown in FIG. 1, the semiconductor manufacturing facility 100 includes a routing mechanism 110, a plurality of pieces of process equipment 120A, 120B, 120C, and 120D (i.e., process devices), a plurality of pieces of testing equipment 130A, 130B, 130C, and 130D (i.e., testing devices), and a plurality of test routing elements 140A, 140B, 140C, and 140D. Throughout this disclosure, the process equipments, testing equipments, and test routing elements will sometimes be referred to generically as process equipment 120, testing equipment 130, and test routing elements 140. In addition, the terms “wafers” will sometimes be used as an abbreviation for semiconductor wafers.

The routing mechanism 110 serves as a control and dispatch element, and operates to move material to be processed (e.g., semiconductor wafers) through the manufacturing facility 100 such that it is subjected to the necessary process operations and any needed testing operations. It receives the material (typically a lot of one or more blank wafers) from an outside source, sends the material to the various pieces of processing equipment 120, receives the material back from the processing equipment 120 or the testing equipment 130, and ultimately sends the final processed material out. The routing mechanism 110 sends the material to as many different pieces of processing equipment 120 as required for final processing, in whatever order is required for the desired level of processing. It also controls the type and amount of testing operations performed on the materials. In various embodiments, the materials moved around by the routing mechanism 110 could be individual semiconductor wafers, carts that contain lots of multiple wafers, or any other desirable collection of material to be processed.

Each of the plurality of pieces of process equipment 120A, 120B, 120C, and 120D performs some kind of semiconductor processing on material sent to it. Each piece of process equipment 120 could have a single processing operation it performs, or could be programmable to perform multiple processing operations as desired. The process equipment 120 can include wet or dry etching equipment, chemical-mechanical planarization (CMP) equipment, diffusion equipment, lithography equipment, probes, or any other kind of process equipment that might be used in a semiconductor fabrication operation.

Each of the plurality of pieces of testing equipment 130A, 130B, 130C, and 130D performs some kind of testing operation on material sent to it. Each piece of testing equipment 130 could have a single testing operation it performs, or could be programmable to perform multiple testing operations as desired. Typically, a piece of testing equipment 130 will be associated with a given piece of processing equipment 120 and will perform tests necessary to determine if the processing operation performed by that piece of processing equipment 120 was done properly. The testing equipment 130 can include devices for measuring layer dimensions (e.g., thickness, depth, width, length, volume, etc.), devices for detecting physical or operational parameters (e.g., resistance, capacitance, current, etc.), devices for measuring wafer bow or stress, or any other kind of testing equipment that could identify a parameter that would assist in determining whether a fabrication process was performed correctly.

Each of the plurality of test routing elements 140A, 140B, 140C, and 140D serves to receive material that has been processed by one of the pieces of process equipment 120, and, based on control signals, either route the material to a corresponding piece of testing equipment 130 or route the material back to the routing mechanism 110.

The semiconductor manufacturing facility 100 can thus perform the processing on individual materials (e.g., semiconductor wafers or lots of multiple wafers) to create a finished wafer product. And since the testing is dynamically controllable, its frequency and selection can be altered to meet the individual needs of the particular processing operations. And such dynamic alteration can be performed without the need for human intervention, increasing its speed and decreasing the required overhead.

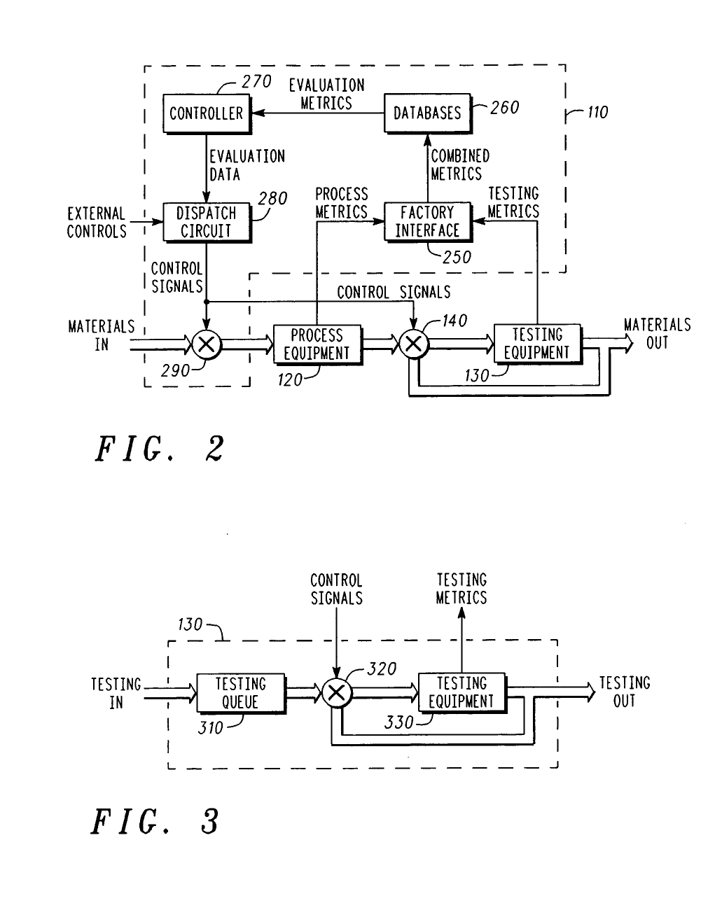

FIG. 2 is a block diagram of a portion of the semiconductor manufacturing facility 100 of FIG. 1 according to disclosed embodiments. FIG. 2 shows the routing mechanism 110, an exemplary piece of process equipment 120, an exemplary piece of testing equipment 130, and an exemplary test routing element 140. In particular, FIG. 2 provide additional detail regarding the control and dispatch element 110. Although only one of each of elements 120, 130, and 140 is shown, this is by way of example only. It should be understood that such connections and operations as are shown with respect to FIG. 2 could apply to any of the plurality of elements 120A, 120B, 120C, 120D, 130A, 130B, 130C, 130D, 140A, 140B, 140C, and 140D.

As shown in FIG. 2, the routing mechanism 110 further includes a factory interface 250, a set of databases 260, a controller 270, a dispatch circuit 280, and a dispatch routing element 290.

The factory interface 250 receives process metrics form the process equipment 120 and testing metrics from the testing equipment 130. The process metrics are information regarding how the processing operations are being performed, and may include process flow information, process settings, fault detection and classification (FDC) information, or any relevant information from the process equipment 120. The testing metrics are information regarding how the testing operations are being performed, as well as information regarding the wafers being tested, and may include statistical process control (SPC) data such as mechanical parameters of a wafer (e.g., wafer stress, wafer bow, etc.), wafer structural or dimensional parameters (e.g., element thickness, depth, width, length, or volume, etc.), wafer electrical properties (e.g., resistance, capacitance, current, etc.), or the like. The factory interface 260 takes these process metrics and testing metrics and send them to the databases 270 as combined metrics.

The set of databases 260 receive the combined metrics from the factor interface 260 and serve as a data storage element to store them in a variety of smaller databases, arranged as appropriate to the combined metrics. By storing all of the information of the combined metrics (including both process metrics and testing metrics) as it is received by the factory interface, the databases 270 maintain real-time information regarding the fabrication process. This information is provided to the controller 270 as evaluation metrics. Although shown as separate databases in this embodiment, alternate embodiments could use fewer databases, concatenating some or all of the combined metrics into fewer databases as necessary. In some embodiments a single database structure could be used in place of all the databases, and could hold all of the required evaluation metrics.

The controller 270 controls the operation of the dispatch circuit 280 based on evaluation metrics received from the databases 260. In particular, by considering the evaluation metrics, the controller 270 determines how to dynamically alter future manufacturing and testing processes based on real-time information about past manufacturing and testing processes. In some embodiments, the controller can include a microprocessor that operates on the evaluation metrics using a set of automated rules for interpreting the evaluation metrics.

The dispatch circuit 280 receives the evaluation data, and based on the evaluation data controls each of the dispatch routing elements 290 and each of the test routing elements 140. In particular, the dispatch circuit 280 instructs the dispatch routing elements 290 when to send wafers or lots to an associated piece of process equipment 120, and instructs the test routing elements 140 when to send wafers or lots to an associated piece of testing equipment 130, and when to send them directly back to the routing mechanism 110. In this way, the dispatch circuit 280 controls when wafer and lots are processed, and when they are tested.

In addition to the evaluation data from the controller 270, the dispatch circuit 280 can also receive external controls through which an operator of the routing mechanism 110 can manually set the control signals. This allows the operator to override the automatic processing when necessary and manually control the processing and testing operations. In some embodiments, this can also involve changing the rules by which the processing and testing operations are controlled and performed.

The dispatch routing element 290 controls the introduction of wafers or lots to an associated piece of process equipment 120. This can allow multiple wafers or lots to be queued up for a piece of process equipment 120, but not sent to the piece of process equipment 120 until the equipment is properly set up for the desired processing operation.

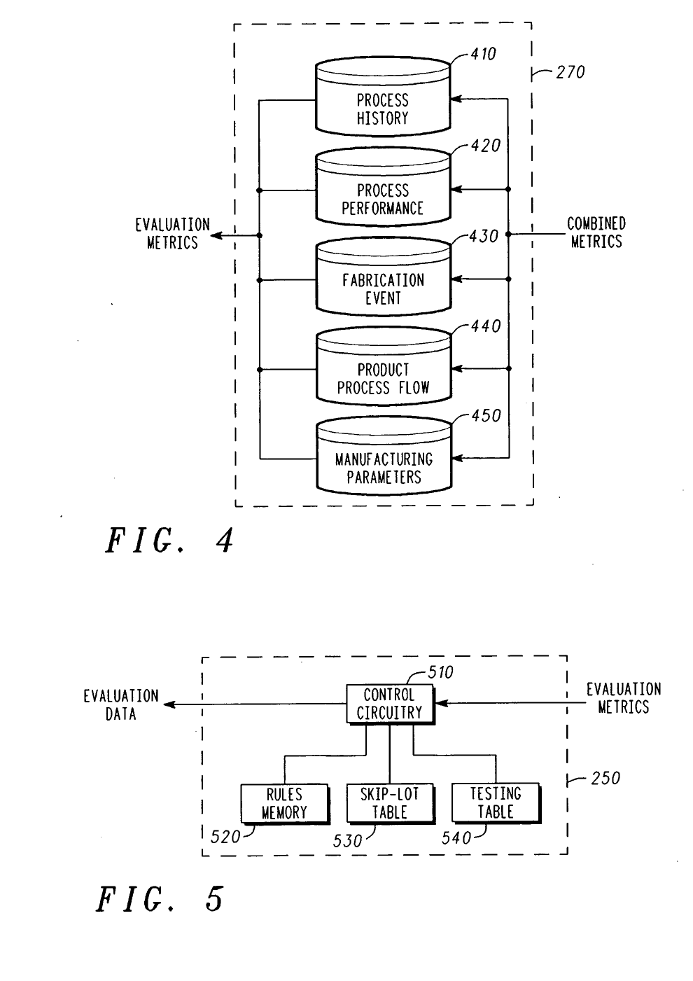

FIG. 3 is a block diagram of a portion of the testing equipment 130 of FIGS. 1 and 2 according to disclosed embodiments. As shown in FIG. 3, the testing equipment 130 further includes a testing queue 310, an internal routing element 320, and a testing element 330.

The testing queue 310 serves to hold one or more wafers or lots in preparation for performing a testing operation in the testing element 330. In some embodiments the testing queue 310 can operate as a first-in-first-out queue, sending wafers or lots for testing based on the order of their arrival. In other embodiments, it could have a more complicated queuing structure in which other parameters, such as wafer priority, availability of processing equipment for subsequent processing operations, etc. control when wafers or lots are sent out of the queue.

The internal routing element 320 operates in response to control signals received from the dispatch circuit 280 in the routing mechanism 110 to either send wafers or lots from the testing queue 310 to the testing element 330, or to send them directly back to the routing mechanism 110.

In some embodiments the testing queue 310 and the internal routing element 320 can be formed as a single unit that routes wafers or lots based on control signals, holding them, sending them to a testing element 330, or sending them back to the routing mechanism 110 as needed.

The testing element 330 performs a testing operation on wafers or lots received from the internal routing element 320 to generate associated testing metrics. It then provides these testing metrics to the factory interface, and sends the wafer or lot back to the routing mechanism 110.

By including the testing queue 310 and internal routing element 320, the manufacturing facility 100 can adjust the overall testing process as more data becomes available. In particular, this allows the dispatch circuit to forward wafers or lots to the testing equipment based on initial evaluation metrics, when such evaluation metrics indicate that testing is desirable. Then, if later processing of information from testing equipment refines the assessment and indicates that there is, in fact, no need for testing, the wafers or lots can be routed from the testing queue 310 back to the routing mechanism 110 without the need for unnecessary testing. This can ensure that a proper level of testing is provided, but save valuable processing time and testing resources when later information indicates that a lower level of testing would be acceptable.

In some embodiments the testing queue 310 and the internal routing element 320 can be eliminated. In such embodiments control of when wafers or lots are sent to the testing elements 330 is performed by the test routing elements 140 alone, and once a wafer or lot is sent to a testing element 330, there is no opportunity to reroute it.

FIG. 4 is a block diagram of a portion of the set of databases 260 of FIG. 2 according to disclosed embodiments. As shown in FIG. 4, the set of databases 260 can include a process history database 410, a process performance database 420, a fabrication event database 430, a product process flow data base 440. and a manufacturing parameter database 450.

The process history database 410 includes information relating to the process history of a given wafer or lot. This can include run-to-run (R2R) data such as process settings (i.e., what was a given piece of processing equipment 120 instructed to do for a given wafer or lot, what each piece of processing equipment 120 actually did for a given wafer or lot, etc.), or non-R2R data related to the processing equipment 120 in general, but not specific to individual process runs.

The process performance database 420 includes information from the testing equipment 130 regarding what the wafers actually look like after a processing operation. This can include statistical process control (SPC) data such as mechanical parameters of a wafer (e.g., wafer stress, wafer bow, etc.), wafer structural or dimensional parameters (e.g., element thickness, depth, width, length, or volume, etc.), wafer electrical properties (e.g., resistance, capacitance, current, etc.), or the like.

The fabrication event database 430 includes data relating to events occurring during a fabrication process. This can include fault detection and classification (FDC) data such data relating to particles or flakes that form on the wafers (e.g., particles per week or particles per day), as well as data and events detected in processing equipment and support systems that indicates an anomalous processing or performance of the equipment during the process sequence.

The product process flow database 440 includes data specific to the operation of the manufacturing facility in general, and the process equipment and testing equipment in particular. It can include data with respect to what processes and tests need to be performed on which wafers or lots, how many wafers or lots are waiting for processing at a given piece of process equipment 120 or testing equipment 140, the priority of any given wafer or lot, etc.

The manufacturing metric database 450 includes information specific to the manufacturing facility 100, which may nevertheless be relevant to wafer or lot routing. This can include facility capacity, wafer starts per week, an indication of the capability of the manufacturing facility 100 to run tests, an indication of which pieces of process equipment 120 and testing equipment 140 are currently offline, etc.

Although five individual databases are shown in this embodiment, this should not be considered limiting. Additional databases can be added as needed for any given embodiment to store whatever data would assist in determining needed testing parameters for a fabrication process. In fact, the database mechanism 260 can be designed to include one or more extra data nodes to easily add on additional databases.

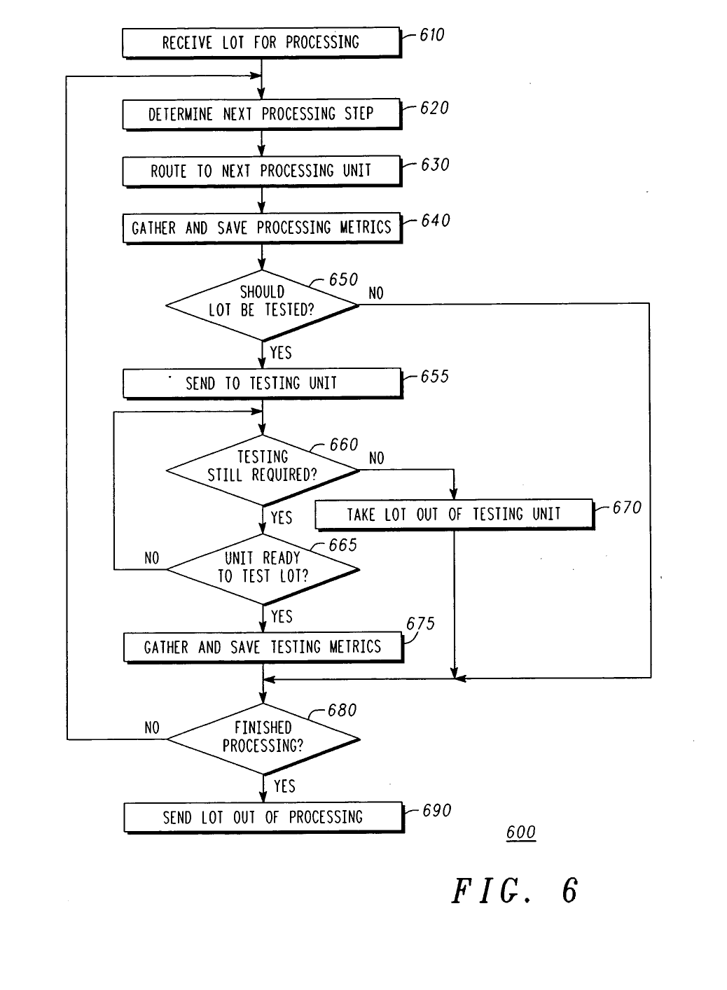

FIG. 5 is a block diagram of a portion of the controller of FIG. 2 according to disclosed embodiments. As shown in FIG. 5, the controller 270 can include control circuitry 510, a rules memory 520, a skip-lot table 530, and a testing table 540.

The control circuitry 510 receives the evaluation metrics from the databases 260, and, based on information in the rules memory 520, the skip-lot table 530, and the testing table 540, generates the evaluation data used by the dispatch circuit to generate the control signals that control operation of the test routing element 140 and dispatch routing element 290. In some embodiments the control circuitry can be a microprocessor.

The rules memory 520 is a memory element that includes the set of processing and testing rules that govern how processing and testing operations in the manufacturing facility 100 are to be handled, i.e., what processes must be performed on what wafers or lots and in what order, under what circumstances wafers or lots must be tested, under what circumstances a wafer or lot can be reclassified to either require testing or eliminate the need for testing, etc. This can include as complex a set of parameters as necessary to account for whatever variety of combined metrics will be stored in the databases 260.

The skip-lot table 530 stores information necessary for the controller 270 to control the operation of the internal routing elements 320 between the testing queue 310 and the testing element 330 in the testing equipment 130. In other words, it contains information relating to the wafers or lots in the various testing queues 310 awaiting testing, and can be used to remove wafers or lots from the testing queues 310, if necessary, as more refined evaluation metrics become available. In some embodiments it could also be used if wafers or lots needed to be added to the testing queues 310.

The testing table 540 stores information necessary for the controller 270 to control the operation of the test routing elements 140 between the processing equipment 120 and the testing equipment 130. In other words, it contains information relating to which wafers or lots should be tested as they leave the various pieces of processing equipment 120, and which can be sent straight back to routing mechanism 110.

The control circuitry 510 can set the data in the skip-lot table 530 and the testing table 540 based on the evaluation metrics received from the databases 270 and the processing and testing rules stored in the rules memory 520. Then, as more process metrics and testing metrics are received at the factory interface, and the evaluation metrics are updated, the control circuitry 510 can update the data in the skip-lot table 530 and the testing table 540 based on these revised evaluation metrics.

In this way, the need for testing can be automatically and dynamically changed as conditions in the manufacturing facility 100 change. For example, if a large number of flaws begin appearing in wafers processed in a particular piece of process equipment 120, the control circuitry 510 may identify these increased errors in the evaluation metrics and put more wafers or lots from that piece of process equipment 120 into an associated piece of testing equipment 130. Contrarily, if flaws begin to decline in wafers processed in a particular piece of process equipment 120, the control circuitry 510 may identify these reduced errors in the evaluation metrics and stop routing as many wafers or lots from that piece of process equipment 120 into an associated piece of testing equipment 130. In such a case, the control circuitry 510 may even take some wafers or lots out of the testing queue 310 of the associated piece of testing equipment 130 to avoid unnecessary testing. Although the initial evaluation metrics may have indicated that a wafer or lot required testing, refinements in the evaluation metrics based on more slowly-generated test data may indicate that the wafer or lot does not, in fact, require testing. Furthermore, this process can be done automatically, without human intervention, further reducing overhead and improving the speed at which changes can be made.

In some embodiments the skip-lot table 530 and the testing table 540 can be separate memory structures. In other embodiments the two can be merged into the same memory structure, which stores data related to the operation of both test routing elements 140 and internal routing elements 320.

FIG. 6 is a flow chart of the operation of the routing mechanism 110 of FIGS. 1 and 2 according to disclosed embodiments.

As shown in FIG. 6, the operation begins when a routing mechanism 110 receives a lot for processing (610). This lot could be a single wafer, a container holding multiple wafers, or whatever arrangement of wafers is desirable for manufacturing.

After receiving the lot, the routing mechanism 110 determines the next processing step for the lot (620). This could be the first, the last, or an intermediate step for the lot. This determination will be made by a controller based on a set of rules governing how the processing of a lot should be performed, and may also be made based on some information relating to the current condition of the manufacturing facility.

Once the next processing step is properly determined (620), the routing mechanism 110 sends the lot to the next processing unit (630). This could involve controlling one or more routing elements, sending the lot via whatever transport mechanism is provided between a holding area and a piece of processing equipment 120, etc.

Then, as the processing equipment 120 performs its processing operation on the lot, the routing mechanism 110 gathers and saves a set of processing metrics provided from the processing equipment, related to the processing operation (640). This can include manufacturing metrics, run-to-run (R2R) data, non-R2R data, fault detection and classification (FDC) data, or the like. Because there may be some delay from when the lot is sent for processing and when processing actually occurs, there may be a delay from when the lot is routed to the next processing unit (620) and when processing metrics are gathered and saved (630).

Once the lot is finished processing and the process metrics are gathered and saved (630), the routing mechanism 110 determines whether the lot should be tested (650). This determination can be made based on a set of rules that govern when lots should be tested, along with evaluation metrics gathered from current and previous process and testing operations.

If the routing mechanism 110 determines that the lot requires testing, (650), it sends the lot to the proper testing unit (655).This could involve controlling one or more routing elements, sending the lot via whatever transport mechanism is provided between the processing equipment 120 and the testing equipment 130, etc.

Because there may be some delay from when the lot is sent for testing and when testing actually occurs, the routing mechanism 110 will have to monitor when a given testing unit is ready to test a lot. In addition, since process and testing metrics are constantly being provided to the routing mechanism 110, the need for testing of the lot may also change.

Thus, after the testing mechanism is sent to the next testing unit (655), the routing mechanism 110 will repeatedly determine whether testing is still required for the lot (660) and whether the testing unit is ready to test the lot (665).

If at any time the routing mechanism 110 determines that testing is no longer required for the lot, it removes the lot from the testing unit (670) and bypasses any gathering of testing data.

If the testing unit is not ready to test the lot, then the processing repeats the two determining operations (660 and 665) until either the testing unit is ready to test the lot, or the lot is removed from the unit entirely.

Once the testing equipment 130 performs its testing operation on the lot (assuming it still needs to), the routing mechanism 110 gathers and saves a set of testing metrics provided from the processing equipment, related to the testing operation (675). This can include statistical process control (SPC) data, defectivity information, or any other relevant information that might come out of a testing operation.

If, however, the routing mechanism 110 determines that the lot does not requires testing, (660) it omits the operations of determining whether the unit is ready to test (665), and the operation of gathering testing metrics (675).

Once either the lot is finished testing and the testing metrics are gathered and saved (675), or it is determined that no testing is required, the routing mechanism 110 then determines whether the lot is finished processing (680). This determination can be made based on a set of rules that govern what processing should be performed on the lots, and what operational thresholds must be met by the wafers to be manufactured, along with evaluation metrics gathered from current and previous process and testing operations. One reason that the routing mechanism 110 may decide that the lot is finished processing is when all of the required processing steps have been performed on the lot. Another reasons the routing mechanism 110 may decide that the lot is finished processing is if the evaluation metrics gathered during one or more processing or testing operations indicate that one or more wafers in the lot are defective.

If further processing is required, the routing mechanism 110 again determines the next processing step (620), and the operation repeats itself as often as necessary.

If no further processing is required, then the lot is sent out of processing (690). If the lot meets all required criteria, then it is designated as a successfully-manufactured wafer. And if the lot does not meet its required criteria, it is designated as a failed wafer. In alternate embodiments, it is also possible for there to be multiple categories of success. For example, a set of military specifications for a chip may have more stringent operational criteria, while a corresponding set of civilian specifications may have less stringent operational criteria. In this case, some wafers may meet the military criteria, some may meet only the civilian criteria, and some may meet neither.

In embodiments in which no secondary determination is made as to whether testing is required after a lot is sent to the next testing unit, the operations and determinations (660 and 670) can be omitted.

Furthermore, although FIG. 6 shows the control of a single lot as it passes processing operations and testing operations, the routing mechanism 110 may be simultaneously controlling multiple lots as they each pass through a variety of processing and testing operations.

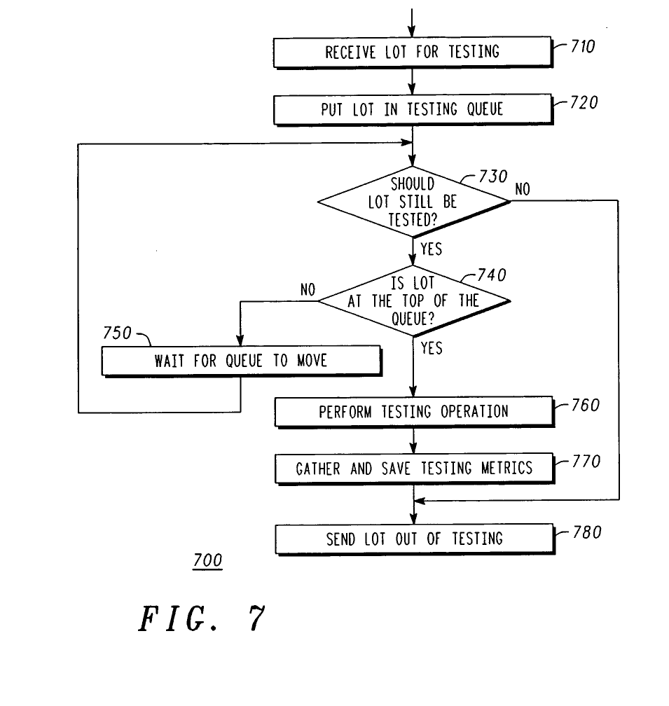

FIG. 7 is a flow chart of the operation of the testing equipment 130 of FIGS. 1-3 according to disclosed embodiments.

As shown in FIG. 7, operation begins when a piece of testing equipment 130 receives a lot for testing (710). At this point, the testing equipment places the lot in a testing queue to await its turn to be tested (720).

As the lot sits in the testing queue, a relevant controller repeatedly determines whether the lot still needs to be tested (730) and whether the lot is at the top of the testing queue (740). It's possible that as the lot waits in the testing queue, and new process and testing metrics are generated, a refined prediction of errors will classify the lot as not requiring testing.

If the lot still requires testing (730) and is not at the top of the testing queue (740), the controller waits for the testing queue to move (750), and again determines whether the lot is at the top of the testing queue (730) and whether it still requires testing.

If the lot still requires testing (730) and is at the top of the testing queue (740), then the testing equipment performs the testing operation on the lot (760), gathers testing metrics related to the testing operation and sends them to a central database (770), and then sends the lot out of testing (780).

If at any time, however, the controller determines that the lot no longer requires testing (730), then the controller removes the lot from the testing queue and sends the lot out of testing (780) without performing the testing and metric gathering operations (760 and 770).

This disclosure is intended to explain how to fashion and use various embodiments in accordance with the invention rather than to limit the true, intended, and fair scope and spirit thereof. The foregoing description is not intended to be exhaustive or to limit the invention to the precise form disclosed. Modifications or variations are possible in light of the above teachings. The embodiment(s) was chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims, as may be amended during the pendency of this application for patent, and all equivalents thereof, when interpreted in accordance with the breadth to which they are fairly, legally, and equitably entitled. The various circuits described above can be implemented in discrete circuits or integrated circuits, as desired by implementation.

What is claimed is:

1. A semiconductor manufacture and testing device, comprising:
a process device configured to perform a semiconductor processing operation on a semiconductor wafer;
a testing device configured to perform a testing operation on the semiconductor wafer and generate real-time testing metrics relating to the testing operation;
a data storage element configured to store the real-time testing metrics as stored testing metrics;
a control and dispatch element configured to receive the stored testing metrics and generate dispatch control signals based on the stored testing metrics and a set of evaluation rules; and
a test routing element located between the process element and the testing element, and configured to route the semiconductor wafer either from the process element to the testing element or from the process element around the testing element, based the dispatch control signals.

2. The apparatus of claim 1, wherein the real-time testing metrics includes statistical process control (SPC) data with respect to the semiconductor wafer.

3. The apparatus of claim 2, wherein the SPC data includes wafer mechanical parameters of a wafer, wafer dimensional parameters, and wafer electrical properties.

4. The apparatus of claim 1,
wherein the process device is further configured to generate real-time process metrics relating to the processing operation,
wherein the data storage element is further configured to store the real-time process metrics as stored process metrics,
wherein the a control and dispatch element is further configured to receive the stored process metrics and generate the dispatch control signals based on the stored testing metrics, the stored process metrics, and the set of evaluation rules.

5. The apparatus of claim 1, wherein the real-time process metrics includes at least one of process history data for the semiconductor wafer, process history data for the process device, data relating to an operational status of the semiconductor manufacture and testing device.

6. A semiconductor manufacture and testing device, comprising:
a testing queue configured to receive and hold a semiconductor wafer in preparation for a testing operation;
a testing element configured to perform the testing operation on the semiconductor wafer and generate real-time testing metrics relating to the testing operation;
an internal routing element located between the testing queue and the testing element, and configured to route the semiconductor wafer either from the testing queue to the testing element or from the testing queue around the testing element, without performing the testing operation on the semiconductor wafer, based upon dispatch control signals;
a data storage element configured to store the real-time testing metrics as stored testing metrics;
a control and dispatch element configured to receive the stored testing metrics and generate the dispatch control signals based on the stored testing metrics and a set of evaluation rules; and
a test routing element located before the testing queue and configured to receive the semiconductor wafer and to route it either to the testing queue or around the testing queue and the testing element, without performing the testing operation on the semiconductor wafer, based on the dispatch control signals.

7. The apparatus of claim 6, wherein the real-time testing metrics includes statistical process control (SPC) data with respect to the semiconductor wafer.

8. The apparatus of claim 7, wherein the SPC data includes wafer mechanical parameters of a wafer, wafer dimensional parameters, and wafer electrical properties.

9. The apparatus of claim 6, further comprising:
a process device located before the test routing element and configured to perform a semiconductor processing operation on a semiconductor wafer,
wherein the process device is further configured to generate real-time process metrics relating to the processing operation,
wherein the data storage element is further configured to store the real-time process metrics as stored process metrics,
wherein the a control and dispatch element is further configured to receive the stored process metrics and generate the dispatch control signals based on the stored testing metrics, the stored process metrics, and the set of evaluation rules.

10. The apparatus of claim 9, wherein the real-time process metrics includes at least one of process history data for the semiconductor wafer, process history data for the process device, data relating to an operational status of the semiconductor manufacture and testing device.

11. A method of fabricating semiconductor devices, comprising:
performing a current semiconductor processing operation on a semiconductor wafer;
generating real-time process metrics relating to the current semiconductor processing operation;
storing the real-time process metrics in a set of stored evaluation metrics;
generating dispatch control signals based on the set of stored evaluation metrics and a set of evaluation rules; and
determining whether the semiconductor wafer needs to be tested based on the dispatch control signals.

12. The method of claim 11, further comprising:
performing a testing operation on the semiconductor wafer when the dispatch control signals indicates that testing should be performed;
generating real-time testing metrics relating to the testing operation; and
storing the real-time testing metrics in the evaluation metrics.

13. The method of claim 11, wherein the real-time testing metrics includes wafer mechanical parameters of a wafer, wafer dimensional parameters, and wafer electrical properties.

14. The method of claim 11, further comprising: routing the semiconductor wafer to a next processing operation when the dispatch control signals indicates that testing should not be performed.

15. The method of claim 11, wherein the real-time process metrics includes at least one of process history data for the semiconductor wafer, process history data for the process device, data relating to an operational status of the semiconductor manufacture and testing device.

16. The method of claim 11, further comprising: storing initial evaluation metrics prior to performing the semiconductor processing operation on the semiconductor wafer.

17. A method of fabricating semiconductor devices, comprising:
receiving a semiconductor wafer;
determining whether the semiconductor wafer needs to be tested based on dispatch control signals;
performing a testing operation on the semiconductor wafer;
storing the real-time testing metrics in a set of evaluation metrics; and
altering the dispatch control signals based on the set of evaluation testing metrics and a set of evaluation rules.

18. The method of claim 17, further comprising:
performing a current semiconductor processing operation on the semiconductor wafer prior to determining whether the semiconductor wafer needs to be tested;
generating real-time process metrics relating to the current semiconductor processing operation;
storing the real-time process metrics in the set of evaluation metrics; and
generating the dispatch control signals based on the stored evaluation metrics and the set of evaluation rules.

19. The method of claim 18, wherein the real-time process metrics includes at least one of process history data for the semiconductor wafer, process history data for the process device, data relating to an operational status of the semiconductor manufacture and testing device.

20. The method of claim 17, wherein the real-time testing metrics includes wafer mechanical parameters of a wafer, wafer dimensional parameters, and wafer electrical properties.

21. The method of claim 17, further comprising: routing the semiconductor wafer to a next processing operation when the dispatch control signals indicates that testing should not be performed.

22. A semiconductor manufacture and testing device, comprising:
means for receiving a semiconductor wafer;
means for determining whether the semiconductor wafer needs to be tested based on dispatch control signals;
means for performing a testing operation on the semiconductor wafer;
means for storing the real-time testing metrics in a set of evaluation metrics; and
means for altering the dispatch control signals based on the set of evaluation testing metrics and a set of evaluation rules.

23. The method of claim 22, further comprising:
means for performing a current semiconductor processing operation on the semiconductor wafer prior to determining whether the semiconductor wafer needs to be tested;
means for generating real-time process metrics relating to the current semiconductor processing operation;
means for storing the real-time process metrics in the set of evaluation metrics; and
means for generating the dispatch control signals based on the stored evaluation metrics and the set of evaluation rules.

24. The method of claim 23, wherein the real-time process metrics includes at least one of process history data for the semiconductor wafer, process history data for the process device, data relating to an operational status of the semiconductor manufacture and testing device.

25. The method of claim 22, wherein the real-time testing metrics includes wafer mechanical parameters of a wafer, wafer dimensional parameters, and wafer electrical properties.

26. The method of claim 22, further comprising means for routing the semiconductor wafer to a next processing operation when the dispatch control signals indicates that testing should not be performed.
